(19) United States
(12) Patent Application Publication
(10) Pub. No.: US 2026/0013152 A1
(43) Pub. Date: Jan. 8, 2026

(54) SEMICONDUCTOR DEVICE AND METHOD OF MAKING

(71) Applicant: Taiwan Semiconductor Manufacturing Company Limited, Hsin-Chu (TW)

(72) Inventors: Po-June CHEN, New Taipei City (TW); Chih-Yu TSENG, Hsinchu County (TW); Wang Kuo LIANG, Hsinchu City (TW)

(21) Appl. No.: 18/764,604

(22) Filed: Jul. 5, 2024

(51) Int. Cl. H10D 1/68

(52) U.S. Cl. CPC H10D 1/692

(57) ABSTRACT

A semiconductor device is provided. The semiconductor device includes a first metal-insulator-metal (MIM) capacitor and a second MIM capacitor. The first MIM capacitor includes a first electrode, a second electrode, and a first insulation structure between the first electrode and the second electrode. The second MIM capacitor includes the second electrode, a third electrode, and a second insulation structure between the second electrode and the third electrode.

### BACKGROUND

Semiconductor devices are used in a multitude of electronic devices, such as mobile phones, laptops, desktops, tablets, watches, gaming systems, and various other industrial, commercial, and consumer electronics. Semiconductor devices generally comprise semiconductor portions and wiring portions formed inside the semiconductor portions.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates a cross-sectional view of a semiconductor device at a stage of fabrication, in accordance with some embodiments.

FIG. 2 illustrates a cross-sectional view of a semiconductor device at a stage of fabrication, in accordance with some embodiments.

FIG. 3 illustrates a cross-sectional view of a semiconductor device at a stage of fabrication, in accordance with some embodiments.

FIG. 4 illustrates a cross-sectional view of a semiconductor device at a stage of fabrication, in accordance with some embodiments.

FIG. 5 illustrates a cross-sectional view of a semiconductor device at a stage of fabrication, in accordance with some embodiments.

FIG. 6 illustrates a cross-sectional view of a semiconductor device at a stage of fabrication, in accordance with some embodiments.

FIG. 7 illustrates a cross-sectional view of a semiconductor device at a stage of fabrication, in accordance with some embodiments.

FIG. 8 illustrates a cross-sectional view of a semiconductor device at a stage of fabrication, in accordance with some embodiments.

FIG. 9 illustrates a cross-sectional view of a semiconductor device at a stage of fabrication, in accordance with some embodiments.

FIG. 10 illustrates a cross-sectional view of a semiconductor device at a stage of fabrication, in accordance with some embodiments.

FIG. 11 illustrates a cross-sectional view of a semiconductor device at a stage of fabrication, in accordance with some embodiments.

FIG. 12 illustrates a cross-sectional view of a semiconductor device at a stage of fabrication, in accordance with some embodiments.

FIG. 13 illustrates a cross-sectional view of a semiconductor device at a stage of fabrication, in accordance with some embodiments.

FIG. 14 illustrates a cross-sectional view of a semiconductor device at a stage of fabrication, in accordance with some embodiments.

FIG. 15 illustrates a cross-sectional view of a semiconductor device at a stage of fabrication, in accordance with some embodiments.

FIG. 16 illustrates a cross-sectional view of a semiconductor device at a stage of fabrication, in accordance with some embodiments.

FIG. 17 illustrates a cross-sectional view of a semiconductor device at a stage of fabrication, in accordance with some embodiments.

FIG. 18 illustrates a cross-sectional view of a semiconductor device at a stage of fabrication, in accordance with some embodiments.

FIG. 19 illustrates a cross-sectional view of a semiconductor device at a stage of fabrication, in accordance with some embodiments.

FIG. 20A illustrates a cross-sectional view of a semiconductor device at a stage of fabrication, in accordance with some embodiments.

FIG. 20B illustrates an enlarged representation of a section of a semiconductor device, in accordance with some embodiments.

FIG. 20C illustrates an enlarged representation of a section of a semiconductor device, in accordance with some embodiments.

### DETAILED DESCRIPTION

The following disclosure provides several different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact and may also include embodiments in which additional features may be formed between the first and second features, such that the first and second features may not be in direct contact. In addition, the present disclosure may repeat reference numerals or letters in the various examples. This repetition is for the purpose of simplicity and clarity and does not in itself dictate a relationship between the various embodiments or configurations discussed.

Further, spatially relative terms, such as “beneath,” “below,” “lower,” “above,” “upper” and the like, may be used herein for ease of description to describe one element or feature's relationship to other element(s) or feature(s) as illustrated in the figures. The spatially relative terms are intended to encompass different orientations of the device in use or operation in addition to the orientation illustrated in the figures. The apparatus may be otherwise oriented (rotated 90 degrees or at other orientations) and the spatially relative descriptors used herein may likewise be interpreted accordingly.

The term “overlying” and/or the like may be used to describe one element or feature being vertically coincident with and at a higher elevation than another element or feature. For example, a first element overlies a second element if the first element is at a higher elevation than the second element and at least a portion of the first element is vertically coincident with at least a portion of the second element.

The term “underlying” and/or the like may be used to describe one element or feature being vertically coincident with and at a lower elevation than another element or feature. For example, a first element underlies a second element if the first element is at a lower elevation than the second element and at least a portion of the first element is vertically coincident with at least a portion of the second element.

The term “over” may be used to describe one element or feature being at a higher elevation than another element or feature. For example, a first element is over a second element if the first element is at a higher elevation than the second element.

The term “under” may be used to describe one element or feature being at a lower elevation than another element or feature. For example, a first element is under a second element if the first element is at a lower elevation than the second element.

A semiconductor device has a first capacitor and a second capacitor. The first capacitor and the second capacitor share a first electrode. In some embodiments, the first capacitor is a first metal-insulator-metal (MIM) capacitor comprising (i) a second electrode on a first side of the first electrode, and (ii) a first insulation structure between the second electrode and the first electrode. In some embodiments, the second capacitor is a second MIM capacitor comprising (i) a third electrode] on a second side of the first electrode, and (ii) a second insulation structure between the third electrode and the first electrode. In some embodiments, components are arranged in a horizontal stack in a dielectric layer to implement a dual-capacitor structure comprising the first capacitor and the second capacitor. In some embodiments, the dual-capacitor structure provides for at least one of (i) increased quantity of capacitors in the semiconductor device as a result of capacitors taking up less space, such as due, at least in part, to the first capacitor and the second capacitor sharing the first electrode, (ii) enlarged MIM capacitors in parallel, (iii) reduced size of the semiconductor device as a result of capacitors taking up less space, such as due, at least in part, to the first capacitor and the second capacitor sharing the first electrode, etc.

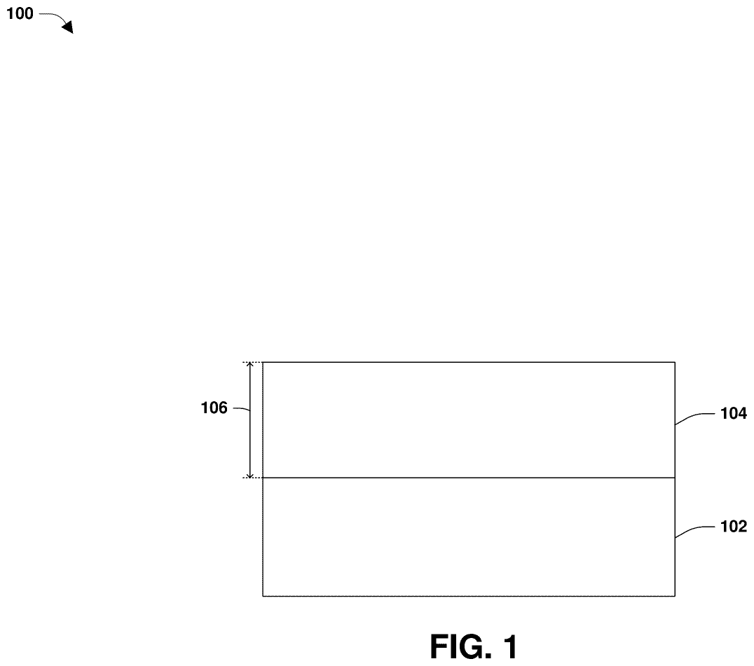

FIGS. 1-20C illustrate cross-sectional views of a semiconductor device 100 at various stages of fabrication, in accordance with some embodiments. FIG. 1 illustrates the semiconductor device 100 according to some embodiments. The semiconductor device 100 comprises a semiconductor body 102 and a first metal layer 104 formed over the semiconductor body 102. The semiconductor body 102 comprises at least one of a substrate, an epitaxial layer, a silicon-on-insulator (SOI) structure, a wafer, or a die formed from a wafer. The semiconductor body 102 comprises at least one of silicon, germanium, carbide, arsenide, gallium, arsenic, phosphide, indium, antimonide, SiGe, SiC, GaAs, GaN, GaP, InGaP, InP, InAs, InSb, GaAsP, AlInAs, AlGaAs, GaInAs, GaInP, GaInAsP, or other suitable material. The semiconductor body 102 comprises at least one of monocrystalline silicon, crystalline silicon with a <100> crystallographic orientation, crystalline silicon with a <110> crystallographic orientation, crystalline silicon with a <111> crystallographic orientation or other suitable material. In some embodiments, the semiconductor body 102 comprises one or more dopants. Other structures and/or configurations of the semiconductor body 102 are within the scope of the present disclosure.

One, some or all vias of the set of vias comprise at least one of a metal, a metal alloy, or other suitable material. The first metal layer 104 comprises at least one of a metal, a metal alloy, or other suitable material. Embodiments are contemplated in which the first metal layer 104 comprises a non-metal, such as a conductive non-metal. In some embodiments, the first metal layer 104 comprises at least one of aluminum, copper, or other suitable metal. In some embodiments, the first metal layer 104 comprises aluminum doped with copper. In some embodiments, the first metal layer 104 is an aluminum-rich layer. The first metal layer 104 is formed by at least one of physical vapor deposition (PVD), sputtering, chemical vapor deposition (CVD), plasma enhanced CVD (PECVD), low pressure CVD (LPCVD), atomic layer chemical vapor deposition (ALCVD), ultrahigh vacuum CVD (UHVCVD), reduced pressure CVD (RPCVD), atomic layer deposition (ALD), molecular beam epitaxy (MBE), liquid phase epitaxy (LPE), spin on, growth, or other suitable techniques. The first metal layer 104 at least one of overlies the semiconductor body 102, is in direct contact with a top surface of the semiconductor body 102, or is in indirect contact with the top surface of the semiconductor body 102. A thickness 106 of the first metal layer 104 is at least one of (i) between about 4000 angstroms to about 10000 angstroms, or (ii) between about 6000 angstroms to about 8000 angstroms. Other values of the thickness 106 of the first metal layer 104 are within the scope of the present disclosure.

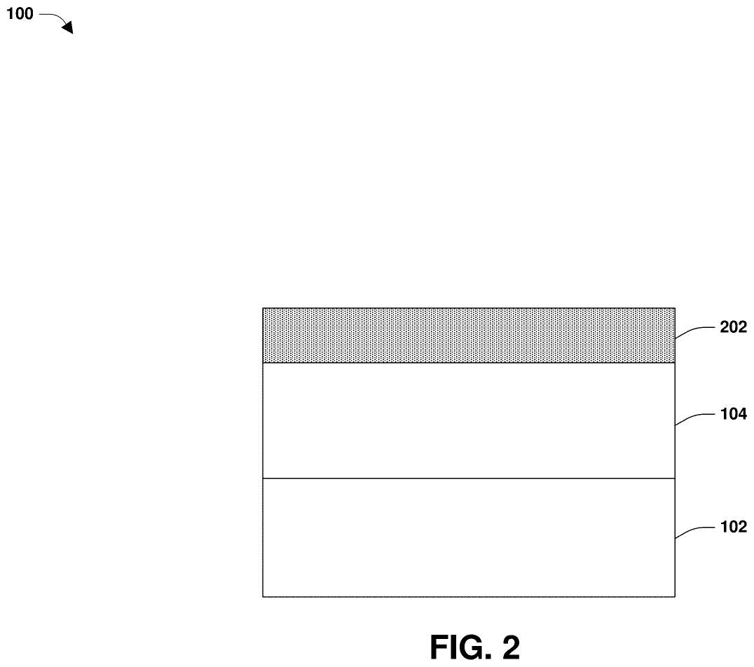

FIG. 2 illustrates a first photoresist 202 formed over the first metal layer 104, according to some embodiments. The first photoresist 202 at least one of overlies the first metal layer 104, is in direct contact with a top surface of the first metal layer 104, or is in indirect contact with the top surface of the first metal layer 104. The first photoresist 202 is formed by at least one of PVD, sputtering, CVD, PECVD, LPCVD, ALCVD, UHVCVD, RPCVD, ALD, MBE, LPE, spin on, growth, or other suitable techniques.

In some embodiments, the first photoresist 202 comprises a light-sensitive material, where properties, such as solubility, of the first photoresist 202 are affected by light. The first photoresist 202 is a negative photoresist or a positive photoresist. With respect to a negative photoresist, regions of the negative photoresist become insoluble when illuminated by a light source, such that application of a solvent to the negative photoresist during a subsequent development stage removes non-illuminated regions of the negative photoresist. A pattern formed in the negative photoresist is thus a negative of a pattern defined by opaque regions of a template, such as a mask, between the light source and the negative photoresist. In a positive photoresist, illuminated regions of the positive photoresist become soluble and are removed via application of a solvent during development. Thus, a pattern formed in the positive photoresist is a positive image of opaque regions of the template, such as a mask, between the light source and the positive photoresist.

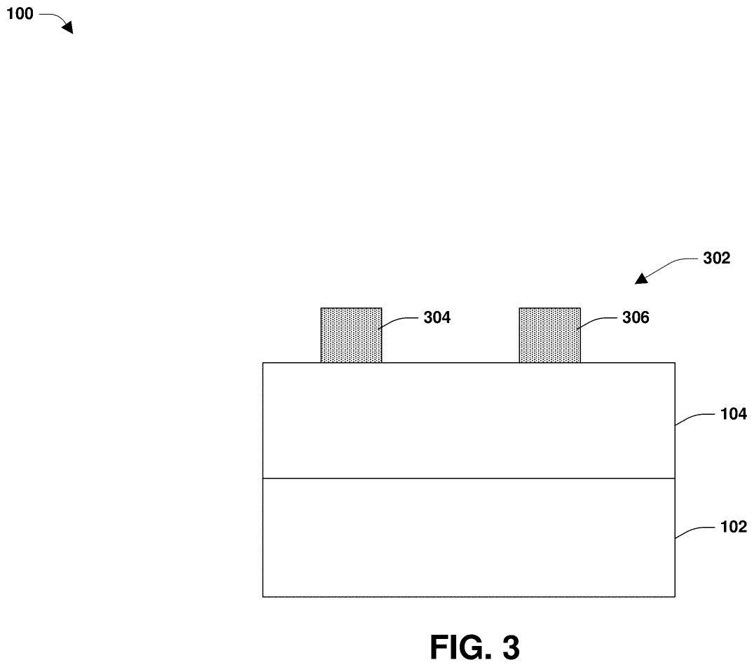

FIG. 3 illustrates a first patterned photoresist 302 formed from the first photoresist 202, according to some embodiments. In some embodiments, the first patterned photoresist 302 comprises at least one of a portion 304, a portion 306, etc. Even though two portions of the first patterned photoresist 302 are depicted, any number of portions of the first patterned photoresist 302 are contemplated.

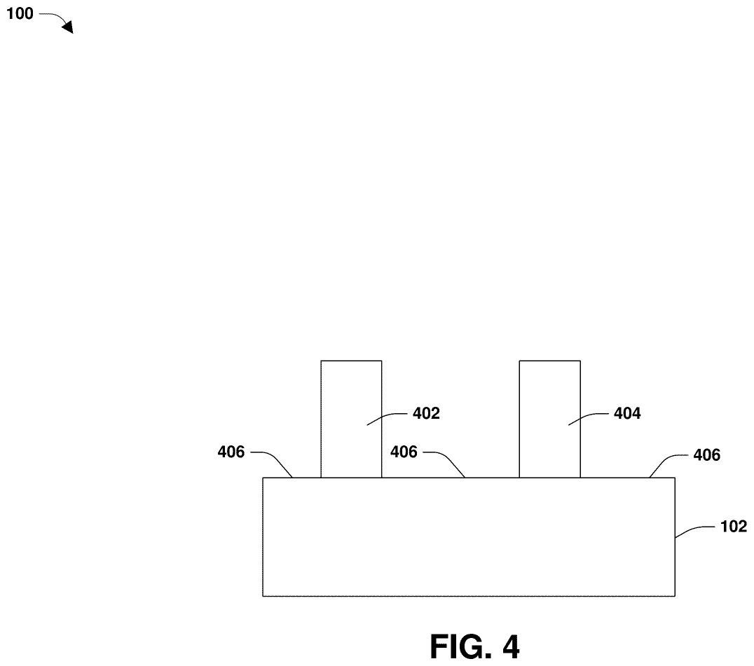

FIG. 4 illustrates use of the first patterned photoresist 302 to remove one or more portions of the first metal layer 104 to form a first set of one or more electrodes comprising at least one of a first electrode 402, a second electrode 404, etc., according to some embodiments. Even though two electrodes of the first set of electrodes are depicted, any number of electrodes of the first set of electrodes are contemplated. In some embodiments, forming the first set of one or more electrodes exposes portions 406 of the semiconductor body 102.

In some embodiments, an etching process is performed to remove portions of the first metal layer 104 to form the first set of electrodes, where one or more openings in the first patterned photoresist 302 allows one or more etchants applied during the etching process to remove portions of the first metal layer 104 while the first patterned photoresist 302 protects or shields portions of the first metal layer 104 that are covered by the first patterned photoresist 302 to form the first set of electrodes. The etching process is at least one of a dry etching process, a wet etching process, an anisotropic etching process, an isotropic etching process, or other suitable etching process. The etching process uses at least one of plasma, fluorine, hydrogen fluoride (HF), diluted HF, sulfur hexafluoride (SF₆), a chlorine compound such as hydrogen chloride (HCl₂), hydrogen sulfide (H₂S), tetrafluoromethane (CF₄), or other suitable material.

In some embodiments, the first patterned photoresist 302 is removed after the first set of electrodes are formed. The first patterned photoresist 302 is removed by at least one of performing a washing process to wash the first patterned photoresist 302 away, stripping the first patterned photoresist 302 away, etching the first patterned photoresist 302, chemical mechanical planarization (CMP), or other suitable techniques.

Embodiments are contemplated in which a mask layer, such as a hard mask layer, is used to form the first set of electrodes. In some embodiments, a first mask layer (not shown) is formed over the first metal layer 104. The first mask layer is formed by at least one of PVD, sputtering, CVD, PECVD, LPCVD, ALCVD, UHVCVD, RPCVD, ALD, MBE, LPE, spin on, growth, or other suitable techniques. In some embodiments, the first mask layer is a hard mask layer. The first mask layer comprises at least one of oxide, nitride, a metal, or other suitable material. The first mask layer is patterned to form a first patterned mask layer (not shown). In some embodiments, the first mask layer is patterned via an etching process. The etching process uses at least one of plasma, fluorine, HF, diluted HF, SF₆, a chlorine compound such as HCl₂, H₂S, CF₄, or other suitable material to remove one or more portions of the first mask layer to form the first patterned mask layer. In some embodiments, the first patterned mask layer includes at least some of the features, relationships with other elements, etc. provided herein with respect to the first patterned photoresist 302. In some embodiments, the first patterned mask layer is used to form the first set of electrodes using one or more of the techniques provided herein with respect to using the first patterned photoresist 302 to form the first set of electrodes. In some embodiments, the first patterned mask layer is removed by at least one of CMP, a washing process, etching, or other suitable techniques.

Other processes and/or techniques for forming the first set of electrodes are within the scope of the present disclosure.

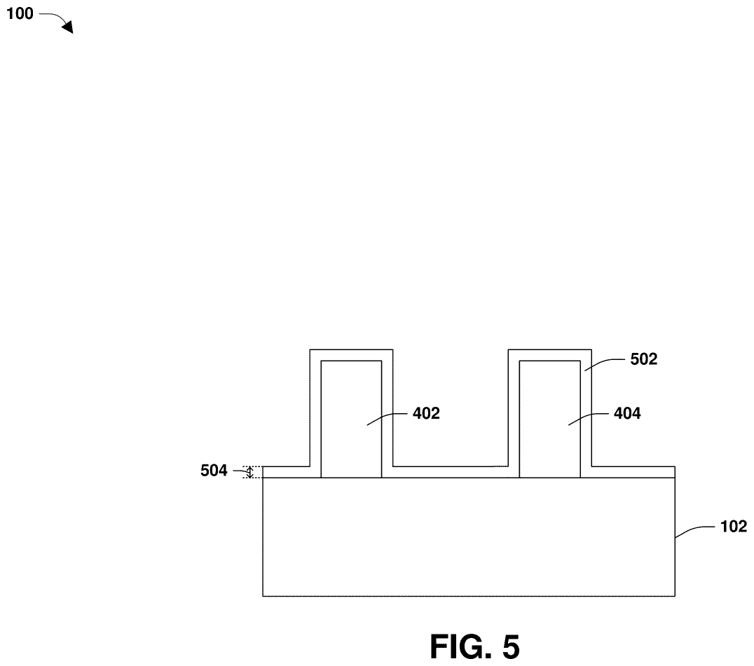

FIG. 5 illustrates an oxide layer 502 formed over the first set of electrodes and the semiconductor body 102, according to some embodiments. The oxide layer 502 at least one of overlies the semiconductor body 102, is in direct contact with a top surface of the semiconductor body 102, or is in indirect contact with the top surface of the semiconductor body 102. The oxide layer 502 is formed by at least one of PVD, sputtering, CVD, PECVD, LPCVD, ALCVD, UHVCVD, RPCVD, ALD, MBE, LPE, spin on, growth, or other suitable techniques. The oxide layer 502 comprises at least one of an oxide semiconductor material, such as silicon oxide, or other suitable material. A thickness 504 of the oxide layer 502 is at least one of (i) between about 100 angstroms to about 1000 angstroms, (ii) between about 300 angstroms to about 500 angstroms, or (iii) about 400 angstroms. Other values of the thickness 504 of the oxide layer 502 are within the scope of the present disclosure.

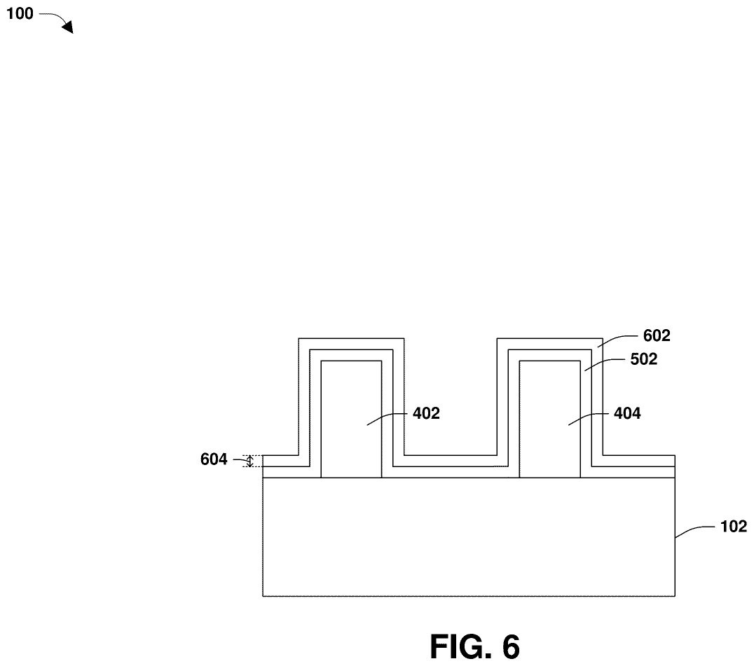

FIG. 6 illustrates a nitride layer 602 formed over the first set of electrodes and the semiconductor body 102, according to some embodiments. The nitride layer 602 at least one of overlies the oxide layer 502, is in direct contact with a top surface of the oxide layer 502, or is in indirect contact with the top surface of the oxide layer 502. The nitride layer 602 is formed by at least one of PVD, sputtering, CVD, PECVD, LPCVD, ALCVD, UHVCVD, RPCVD, ALD, MBE, LPE, spin on, growth, or other suitable techniques. The nitride layer 602 comprises at least one of a nitride semiconductor material, such as silicon nitride, or other suitable material. A thickness 604 of the nitride layer 602 is at least one of (i) between about 100 angstroms to about 1000 angstroms, (ii) between about 300 angstroms to about 500 angstroms, or (iii) about 400 angstroms. Other values of the thickness 604 of the nitride layer 602 are within the scope of the present disclosure.

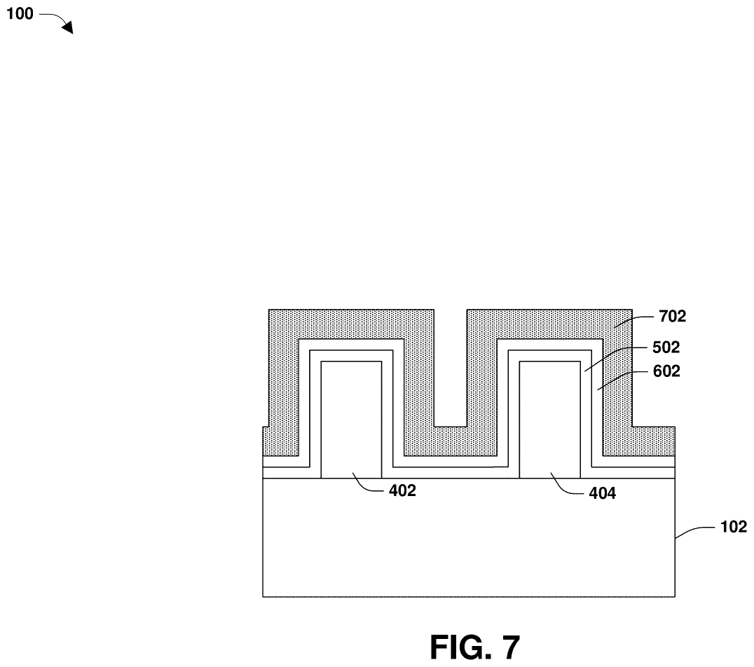

FIG. 7 illustrates a second photoresist 702 formed over the nitride layer 602, according to some embodiments. The second photoresist 702 at least one of overlies the nitride layer 602, is in direct contact with a top surface of the nitride layer 602, or is in indirect contact with the top surface of the nitride layer 602. The second photoresist 702 is formed by at least one of PVD, sputtering, CVD, PECVD, LPCVD, ALCVD, UHVCVD, RPCVD, ALD, MBE, LPE, spin on, growth, or other suitable techniques. In some embodiments, the second photoresist 702 comprises a light-sensitive material, where properties, such as solubility, of the second photoresist 702 are affected by light.

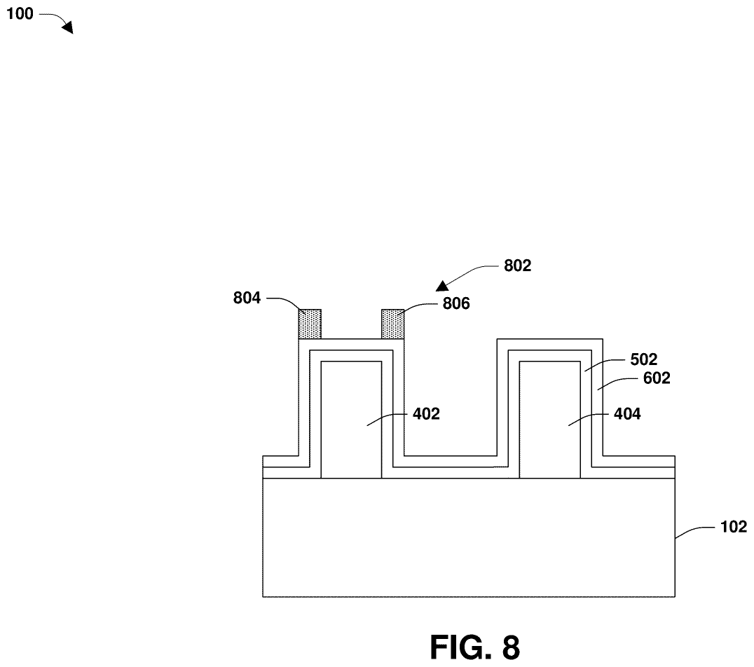

FIG. 8 illustrates a second patterned photoresist 802 formed from the second photoresist 702, according to some embodiments. In some embodiments, the second patterned photoresist 802 comprises at least one of a portion 804, a portion 806, etc. Even though two portions of the second patterned photoresist 802 are depicted, any number of portions of the second patterned photoresist 802 are contemplated.

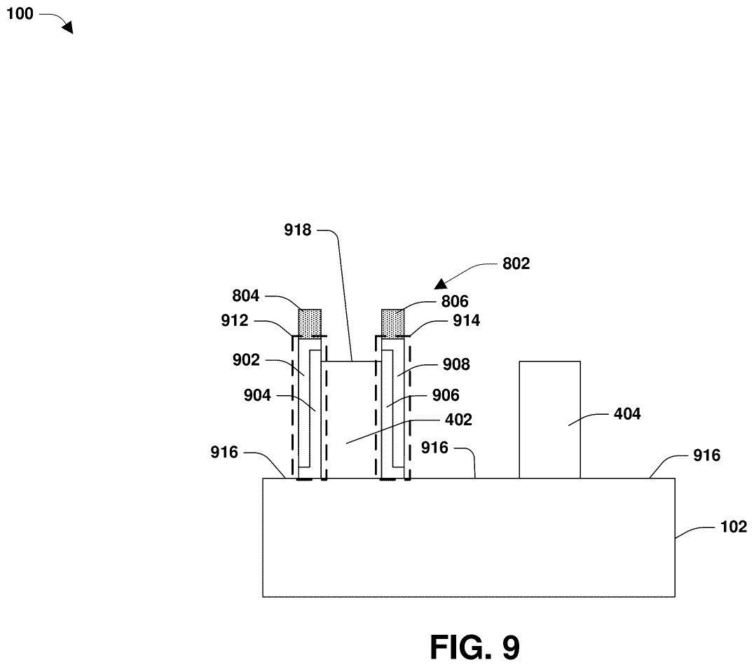

FIG. 9 illustrates use of the second patterned photoresist 802 to remove one or more portions of the nitride layer 602 and the oxide layer 502 to form a set of structures comprising at least one of a first structure 912, a second structure 914 (shown with dashed-line outlines in FIG. 9), etc., according to some embodiments. Even though two structures of the set of structures are depicted, any number of structures of the set of structures are contemplated. In some embodiments, forming the set of structures exposes at least one of a portion 918 of the first electrode 402 or portions 916 of the semiconductor body 102. In some embodiments, the first structure 912 comprises at least one of a portion 902 of the nitride layer 602 or a portion 904 of the oxide layer 502. In some embodiments, the second structure 914 comprises at least one of a portion 908 of the nitride layer 602 or a portion 906 of the oxide layer 502.

In some embodiments, an etching process is performed to remove portions of the nitride layer 602 and/or the oxide layer 502 to form the set of structures, where one or more openings in the second patterned photoresist 802 allows one or more etchants applied during the etching process to remove portions of the nitride layer 602 and/or the oxide layer 502 while the second patterned photoresist 802 protects or shields portions of the nitride layer 602 and/or the oxide layer 502 that are covered by the second patterned photoresist 802 to form the set of structures. The etching process is at least one of a dry etching process, a wet etching process, an anisotropic etching process, an isotropic etching process, or other suitable etching process. The etching process uses at least one of plasma, fluorine, HF, diluted HF, SF₆, a chlorine compound such as HCl₂, H₂S, CF₄, or other suitable material.

In some embodiments, the second patterned photoresist 802 is removed after the set of structures are formed. The second patterned photoresist 802 is removed by at least one of performing a washing process to wash the second patterned photoresist 802 away, stripping the second patterned photoresist 802 away, etching the second patterned photoresist 802, CMP, or other suitable techniques.

Embodiments are contemplated in which a mask layer, such as a hard mask layer, is used to form the set of structures. In some embodiments, a second mask layer (not shown) is formed over the nitride layer 602. The second mask layer is formed by at least one of PVD, sputtering, CVD, PECVD, LPCVD, ALCVD, UHVCVD, RPCVD, ALD, MBE, LPE, spin on, growth, or other suitable techniques. In some embodiments, the second mask layer is a hard mask layer. The second mask layer comprises at least one of oxide, nitride, a metal, or other suitable material. The second mask layer is patterned to form a second patterned mask layer (not shown). In some embodiments, the second mask layer is patterned via an etching process. The etching process uses at least one of plasma, fluorine, HF, diluted HF, SF₆, a chlorine compound such as HCl₂, H₂S, CF₄, or other suitable material to remove one or more portions of the second mask layer to form the second patterned mask layer. In some embodiments, the second patterned mask layer includes at least some of the features, relationships with other elements, etc. provided herein with respect to the second patterned photoresist 802. In some embodiments, the second patterned mask layer is used to form the set of structures using one or more of the techniques provided herein with respect to using the second patterned photoresist 802 to form the set of structures. In some embodiments, the second patterned mask layer is removed by at least one of CMP, a washing process, etching, or other suitable techniques.

Other processes and/or techniques for forming the set of structures are within the scope of the present disclosure.

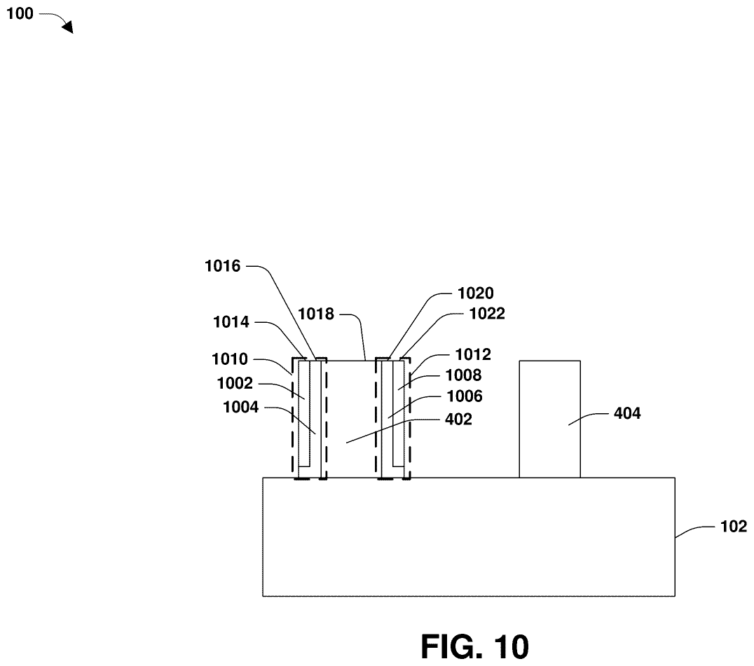

FIG. 10 illustrates removing one or more portions of the set of structures to form a set of insulation structures comprising at least one of a first insulation structure 1010, a second insulation structure 1012 (shown with dashed-line outlines in FIG. 10), etc., according to some embodiments. In some embodiments, the first insulation structure 1010 comprises at least one of (i) a first nitride structure 1002 corresponding to a portion of the nitride layer 602 or (ii) a first oxide structure 1004 corresponding to a portion of the oxide layer 502. In some embodiments, the second insulation structure 1012 comprises at least one of (i) a second nitride structure 1008 corresponding to a portion of the nitride layer 602 or (ii) a second oxide structure 1006 corresponding to a portion of the oxide layer 502.

In some embodiments, the one or more portions are removed by a planarization process comprising at least one of CMP or other suitable techniques. In some embodiments, the planarization process comprises removing top portions of at least one of the first structure 912 (shown in FIG. 9), the second structure 914 (shown in FIG. 9), or the first electrode 402. In some embodiments, the planarization process is performed such that some or all of top surfaces 1014, 1016, 1018, 1020, and/or 1022 (of the first nitride structure 1002, the first oxide structure 1004, the first electrode 402, the second oxide structure 1006, and/or the second nitride structure 1008, respectively) are coplanar with each other.

Other processes and/or techniques for forming the set of insulation structures are within the scope of the present disclosure.

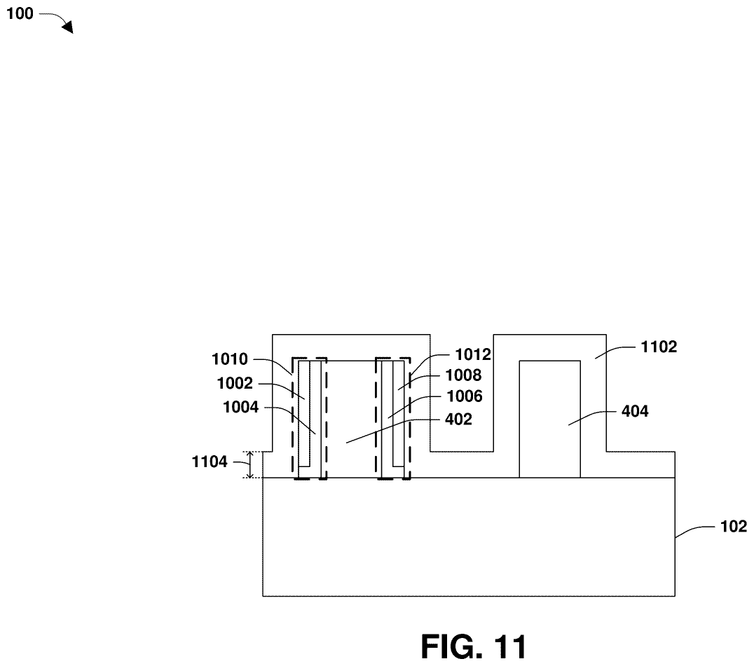

FIG. 11 illustrates a second metal layer 1102 formed over the first set of electrodes and the semiconductor body 102, according to some embodiments. The second metal layer 1102 at least one of overlies the semiconductor body 102, is in direct contact with a top surface of the semiconductor body 102, or is in indirect contact with the top surface of the semiconductor body 102. The second metal layer 1102 is formed by at least one of PVD, sputtering, CVD, PECVD, LPCVD, ALCVD, UHVCVD, RPCVD, ALD, MBE, LPE, spin on, growth, or other suitable techniques. The second metal layer 1102 comprises at least one of titanium or other suitable metal. The second metal layer 1102 comprises a metal nitride, such as titanium nitride. Other materials of the second metal layer 1102 are within the scope of the present disclosure. Embodiments are contemplated in which the second metal layer 1102 comprises a non-metal, such as a conductive non-metal. A thickness 1104 of the second metal layer 1102 is at least one of (i) between about 500 angstroms to about 1500 angstroms, (ii) between about 800 angstroms to about 1200 angstroms, or (iii) about 1000 angstroms. Other values of the thickness 1104 of the second metal layer 1102 are within the scope of the present disclosure.

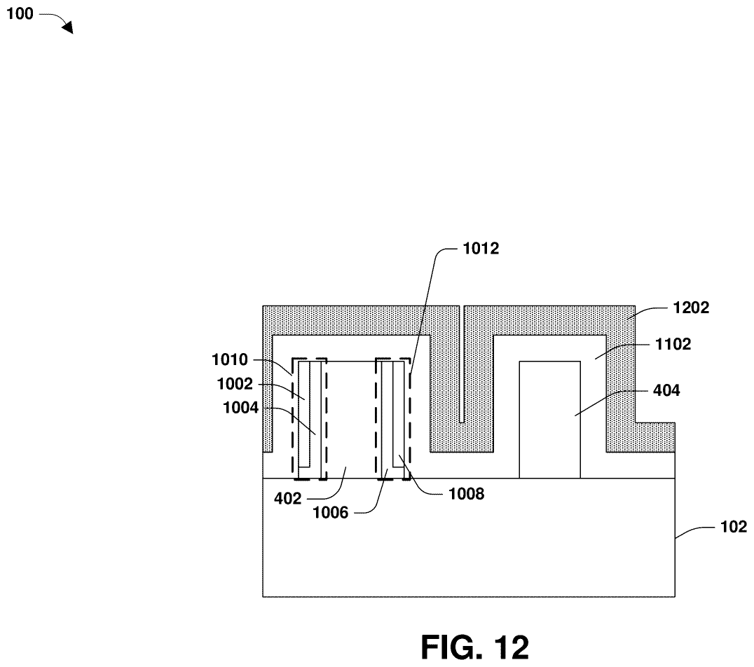

FIG. 12 illustrates a third photoresist 1202 formed over the second metal layer 1102, according to some embodiments. The third photoresist 1202 at least one of overlies the second metal layer 1102, is in direct contact with a top surface of the second metal layer 1102, or is in indirect contact with the top surface of the second metal layer 1102. The third photoresist 1202 is formed by at least one of PVD, sputtering, CVD, PECVD, LPCVD, ALCVD, UHVCVD, RPCVD, ALD, MBE, LPE, spin on, growth, or other suitable techniques. In some embodiments, the third photoresist 1202 comprises a light-sensitive material, where properties, such as solubility, of the third photoresist 1202 are affected by light.

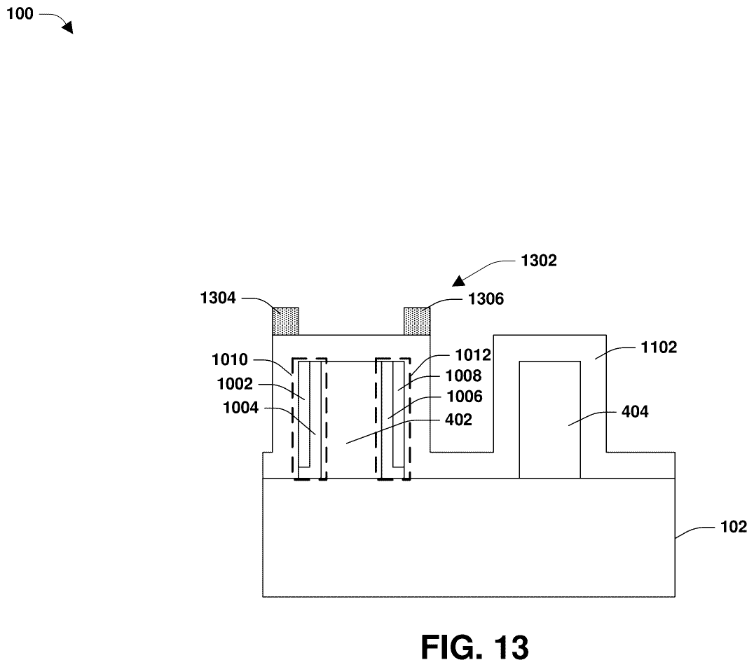

FIG. 13 illustrates a third patterned photoresist 1302 formed from the third photoresist 1202, according to some embodiments. In some embodiments, the third patterned photoresist 1302 comprises at least one of a portion 1304, a portion 1306, etc. Even though two portions of the third patterned photoresist 1302 are depicted, any number of portions of the third patterned photoresist 1302 are contemplated.

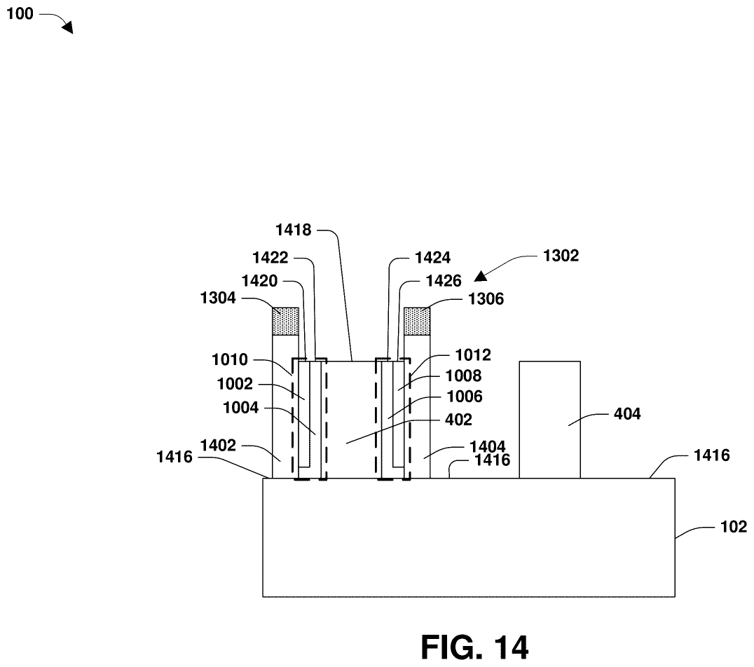

FIG. 14 illustrates use of the third patterned photoresist 1302 to remove one or more portions of the second metal layer 1102 to form a set of metal structures comprising at least one of a first metal structure 1402, a second metal structure 1404, etc., according to some embodiments. Even though two metal structures of the set of metal structures are depicted, any number of metal structures of the set of metal structures are contemplated. In some embodiments, forming the set of metal structures exposes at least one of a portion 1418 of the first electrode 402, a portion 1420 of the first nitride structure 1002, a portion 1422 of the first oxide structure 1004, a portion 1424 of the second oxide structure 1006, a portion 1426 of the second nitride structure 1008, or portions 1416 of the semiconductor body 102. In some embodiments, the first metal structure 1402 comprises a first portion of the second metal layer 1102. In some embodiments, the second metal structure 1404 comprises a second portion of the second metal layer 1102.

In some embodiments, an etching process is performed to remove portions of the second metal layer 1102 to form the set of metal structures, where one or more openings in the third patterned photoresist 1302 allows one or more etchants applied during the etching process to remove portions of the second metal layer 1102 while the third patterned photoresist 1302 protects or shields portions of the second metal layer 1102 that are covered by the third patterned photoresist 1302 to form the set of metal structures. The etching process is at least one of a dry etching process, a wet etching process, an anisotropic etching process, an isotropic etching process, or other suitable etching process. The etching process uses at least one of plasma, fluorine, HF, diluted HF, SF₆, a chlorine compound such as HCl₂, H₂S, CF₄, or other suitable material.

In some embodiments, the third patterned photoresist 1302 is removed after the set of metal structures are formed. The third patterned photoresist 1302 is removed by at least one of performing a washing process to wash the third patterned photoresist 1302 away, stripping the third patterned photoresist 1302 away, etching the third patterned photoresist 1302, CMP, or other suitable techniques.

Embodiments are contemplated in which a mask layer, such as a hard mask layer, is used to form the set of metal structures. In some embodiments, a third mask layer (not shown) is formed over the second metal layer 1102. The third mask layer is formed by at least one of PVD, sputtering, CVD, PECVD, LPCVD, ALCVD, UHVCVD, RPCVD, ALD, MBE, LPE, spin on, growth, or other suitable techniques. In some embodiments, the third mask layer is a hard mask layer. The third mask layer comprises at least one of oxide, nitride, a metal, or other suitable material. The third mask layer is patterned to form a third patterned mask layer (not shown). In some embodiments, the third mask layer is patterned via an etching process. The etching process uses at least one of plasma, fluorine, HF, diluted HF, SF₆, a chlorine compound such as HCl₂, H₂S, CF₄, or other suitable material to remove one or more portions of the third mask layer to form the third patterned mask layer. In some embodiments, the third patterned mask layer includes at least some of the features, relationships with other elements, etc. provided herein with respect to the third patterned photoresist 1302. In some embodiments, the third patterned mask layer is used to form the set of metal structures using one or more of the techniques provided herein with respect to using the third patterned photoresist 1302 to form the set of metal structures. In some embodiments, the third patterned mask layer is removed by at least one of CMP, a washing process, etching, or other suitable techniques.

Other processes and/or techniques for forming the set of metal structures are within the scope of the present disclosure.

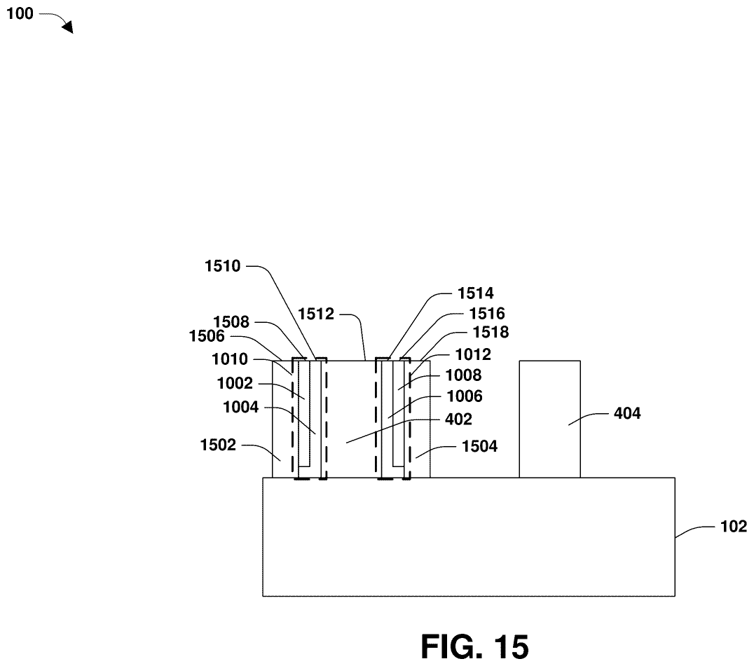

FIG. 15 illustrates removing one or more portions of the set of metal structures to form a second set of electrodes comprising at least one of a third electrode 1502, a fourth electrode 1504, etc., according to some embodiments. Even though two electrodes of the second set of electrodes are depicted, any number of electrodes of the second set of electrodes are contemplated. In some embodiments, the one or more portions of the set of metal structures are removed by a planarization process comprising at least one of CMP or other suitable techniques. In some embodiments, the planarization process comprises removing top portions of at least one of the first metal structure 1402 (shown in FIG. 14), the second metal structure 1404 (shown in FIG. 14), the set of insulation structures, or the first electrode 402 such that some or all of top surfaces 1506, 1508, 1510, 1512, 1514, 1516, and/or 1518 (of the third electrode 1502, the first nitride structure 1002, the first oxide structure 1004, the first electrode 402, the second oxide structure 1006, the second nitride structure 1008, and/or the fourth electrode 1504, respectively) are coplanar with each other.

Other processes and/or techniques for forming the second set of electrodes are within the scope of the present disclosure.

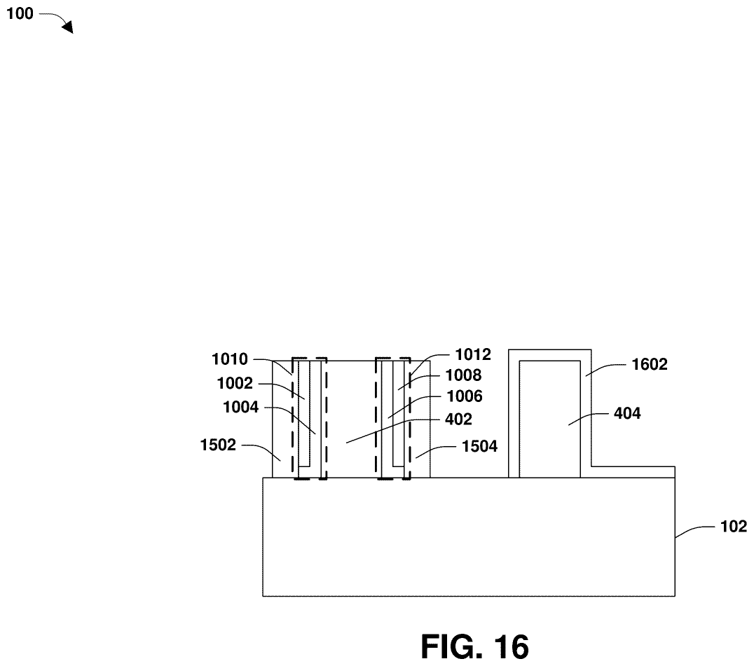

FIG. 16 illustrates a third metal layer 1602 formed over the second electrode 404 and the semiconductor body 102, according to some embodiments. The third metal layer 1602 is formed by at least one of PVD, sputtering, CVD, PECVD, LPCVD, ALCVD, UHVCVD, RPCVD, ALD, MBE, LPE, spin on, growth, or other suitable techniques. The third metal layer 1602 comprises at least one of titanium or other suitable metal. The third metal layer 1602 comprises a metal nitride, such as titanium nitride. Other materials of the second metal layer 1102 are within the scope of the present disclosure. Embodiments are contemplated in which the third metal layer 1602 comprises a non-metal, such as a conductive non-metal.

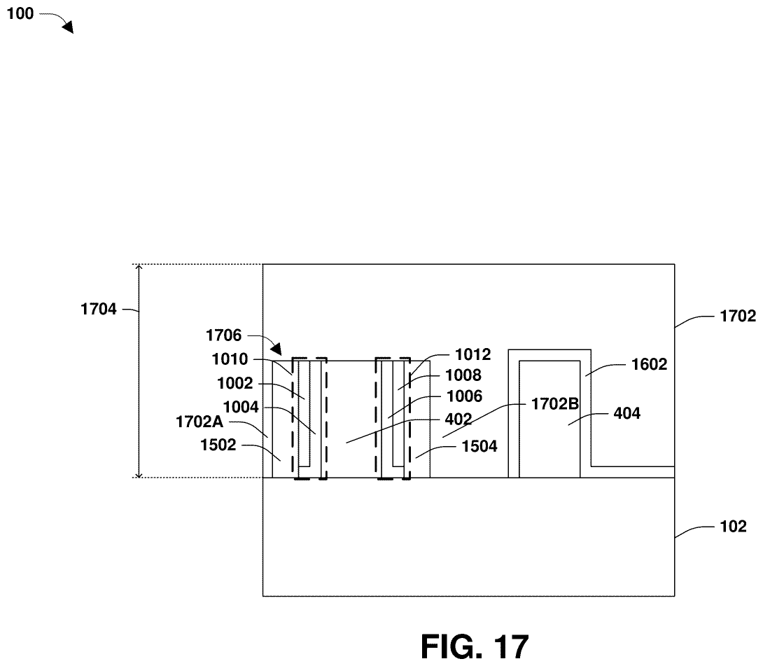

FIG. 17 illustrates a dielectric layer 1702 formed over at least one of the semiconductor body 102, the first set of electrodes, the set of insulation structures, the second set of electrodes, or the third metal layer 1602. The dielectric layer 1702 comprises at least one of an oxide semiconductor material, such as silicon oxide, or other suitable material. In some embodiments, the dielectric layer 1702 comprises an inter-metal dielectric (IMD) layer. The dielectric layer 1702 is formed by at least one of PVD, sputtering, CVD, PECVD, LPCVD, ALCVD, UHVCVD, RPCVD, ALD, MBE, LPE, spin on, growth, or other suitable techniques. The dielectric layer 1702 at least one of overlies the semiconductor body 102, is in direct contact with a top surface of the semiconductor body 102, or is in indirect contact with the top surface of the semiconductor body 102. A thickness 1704 of the dielectric layer 1702 is at least one of (i) between about 6000 angstroms to about 20000 angstroms, or (ii) between about 9000 angstroms to about 16000 angstroms. Other values of the thickness 1704 of the dielectric layer 1702 are within the scope of the present disclosure.

In some embodiments, the semiconductor device 100 comprises a dual-capacitor structure 1706. In some embodiments, the dual-capacitor structure 1706 is disposed in the dielectric layer 1702. In some embodiments, the dual-capacitor structure 1706 is between a first portion 1702A and a second portion 1702B of the dielectric layer 1702. In some embodiments, the dual-capacitor structure 1706 is formed from at least one of the first electrode 402, the first insulation structure 1010, the second insulation structure 1012, the third electrode 1502, or the fourth electrode 1504. In some embodiments, the dual-capacitor structure 1706 comprises (i) a first capacitor comprising the first electrode 402, the first insulation structure 1010, and the third electrode 1502 and (ii) a second capacitor comprising the first electrode 402, the second insulation structure 1012, and the fourth electrode 1504. In some embodiments, the first capacitor is a first metal-insulator-metal (MIM) capacitor. In some embodiments, the second capacitor is a second MIM capacitor. In some embodiments, the first capacitor and the second capacitor share the first electrode 402. In some embodiments, the first electrode 402 serves as a capacitor bottom metal (CBM) electrode for the first capacitor and the second capacitor. In some embodiments, the third electrode 1502 serves as a first capacitor top metal (CTM) electrode for the first capacitor. In some embodiments, the first capacitor stores charge and/or energy in the first insulation structure 1010. In some embodiments, the fourth electrode 1504 serves as a second CTM electrode for the second capacitor. In some embodiments, the second capacitor stores charge and/or energy in the second insulation structure 1012.

In some embodiments, at least one of the first capacitor is a first high linearity capacitor or the second capacitor is a second high linearity capacitor. In some embodiments, a high linearity capacitor (e.g., the first high linearity capacitor or the second high linearity capacitor) is associated with a capacitance that does not change or changes by less than a threshold amount due to temperature changes and/or voltage changes. For example, the capacitance of the high linearity capacitor is stable (within a range of capacitances) throughout a range of temperatures (e.g., TCC temperatures ranging from at least about-40 degrees Celsius to at most about 150 degrees Celsius) of the high linearity capacitor and/or a ranges of voltages (e.g., VCC voltages ranging from at least about-10 volts to at most about 10 volts and/or ranging from at least about-5 volts to at most about 5 volts) applied to the high linearity capacitor. In some embodiments, the high linearity capacitor achieves high linearity due, at least in part, to having an insulation structure (e.g., the first insulation structure 1010 or the second insulation structure 1012) that comprises (i) an oxide structure (e.g., the first oxide structure 1004 or the second oxide structure 1006) with a first capacitance-temperature relationship and/or a first capacitance-voltage relationship and (ii) a nitride structure (e.g., the first nitride structure 1002 or the second nitride structure 1008) with a second capacitance-temperature relationship and/or a second capacitance-voltage relationship. In some embodiments, the first capacitance-temperature relationship is at least partially inverse to the second capacitance-temperature relationship such that the oxide structure and the nitride structure provide a capacitance-temperature relationship with increased linearity, such as due, at least in part, to the first capacitance-temperature relationship associated with the oxide structure at least partially canceling out the second capacitance-temperature relationship associated with the nitride structure. In some embodiments, the first capacitance-voltage relationship is at least partially inverse to the second capacitance-voltage relationship such that the oxide structure and the nitride structure provide a capacitance-voltage relationship with increased linearity, such as due, at least in part, to the first capacitance-voltage relationship associated with the oxide structure at least partially canceling out the second capacitance-voltage relationship associated with the nitride structure. In some embodiments, the capacitance of the high linearity capacitor is a function (e.g., at least one of a linear function or a function with a linearity that exceeds a threshold linearity) of a dimension (e.g., a width) of an insulation structure of the high linearity capacitor, such as a dimension of the first insulation structure 1010 (e.g., a width of the first insulation structure 1010) or a dimension of the second insulation structure 1012 (e.g., a width of the second insulation structure 1012).

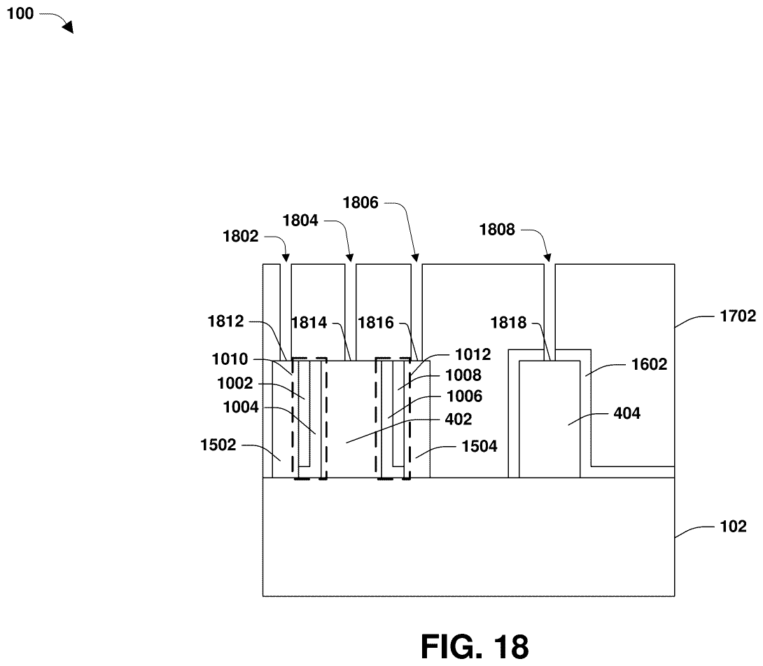

FIG. 18 illustrates a set of trenches formed in one or more layers of the semiconductor device 100, according to some embodiments. In some embodiments, the set of trenches comprises at least one of (i) a first trench 1802 formed in the dielectric layer 1702 to expose a portion 1812 of the third electrode 1502, (ii) a second trench 1804 formed in the dielectric layer 1702 to expose a portion 1814 of the first electrode 402, (iii) a third trench 1806 formed in the dielectric layer 1702 to expose a portion 1816 of the fourth electrode 1504, or (iv) a fourth trench 1808 formed in at least one of the dielectric layer 1702 or the third metal layer 1602 to expose a portion 1818 of the second electrode 404.

According to some embodiments, the set of trenches are formed using a fourth photoresist (not shown). In some embodiments, the fourth photoresist comprises a light-sensitive material, where properties, such as solubility, of the fourth photoresist are affected by light. The fourth photoresist is a negative photoresist or a positive photoresist. In some embodiments, an etching process is performed to remove portions of at least one of the dielectric layer 1702 or the third metal layer 1602 to form the set of trenches, where one or more openings in the fourth photoresist allows one or more etchants applied during the etching process to remove portions of at least one of the dielectric layer 1702 or the third metal layer 1602 to form the set of trenches while the fourth photoresist protects or shields portions of the dielectric layer 1702 and/or the third metal layer 1602 that are covered by the fourth photoresist. The etching process is at least one of a dry etching process, a wet etching process, an anisotropic etching process, an isotropic etching process, or other suitable etching process. The etching process uses at least one of plasma, fluorine, HF, diluted HF, SF₆, a chlorine compound such as HCl₂, H₂S, CF₄, or other suitable material. The fourth photoresist is stripped or washed away after the set of trenches are formed. Other processes and/or techniques for forming the set of trenches are within the scope of the present disclosure. Other processes and/or techniques for forming the set of trenches are within the scope of the present disclosure.

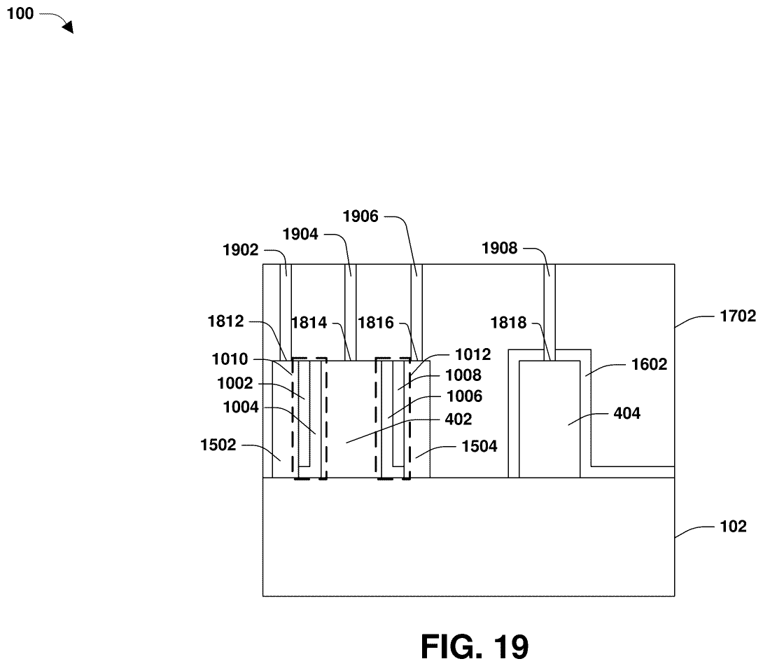

FIG. 19 illustrates a set of vias formed in the set of trenches (shown in FIG. 18) of the semiconductor device 100, according to some embodiments. In some embodiments, the set of vias comprises at least one of (i) a first via 1902 formed in the first trench 1802 (shown in FIG. 18), (ii) a second via 1904 formed in the second trench 1804 (shown in FIG. 18), (iii) a third via 1906 formed in the third trench 1806 (shown in FIG. 18), or (iv) a fourth via 1908 formed in the fourth trench 1808 (shown in FIG. 18). In some embodiments, at least one of (i) the first via 1902 is in contact (e.g., direct contact or indirect contact) with the portion 1812 of the third electrode 1502, (ii) the second via 1904 is in contact (e.g., direct contact or indirect contact) with the portion 1814 of the first electrode 402, (iii) the third via 1906 is in contact (e.g., direct contact or indirect contact) with the portion 1816 of the fourth electrode 1504, or (iv) the fourth via 1908 is in contact (e.g., direct contact or indirect contact) with the portion 1818 of the second electrode 404. One, some or all vias of the set of vias comprise at least one of a metal, a metal alloy, or other suitable material. Embodiments are contemplated in which a via of the set of vias comprises a non-metal, such as a conductive non-metal. In some embodiments, one, some or all vias of the set of vias comprise at least one of aluminum, copper, titanium, or other suitable metal. In some embodiments, the set of vias are formed by at least one of PVD, sputtering, CVD, PECVD, LPCVD, ALCVD, UHVCVD, RPCVD, ALD, MBE, LPE, spin on, growth, or other suitable techniques.

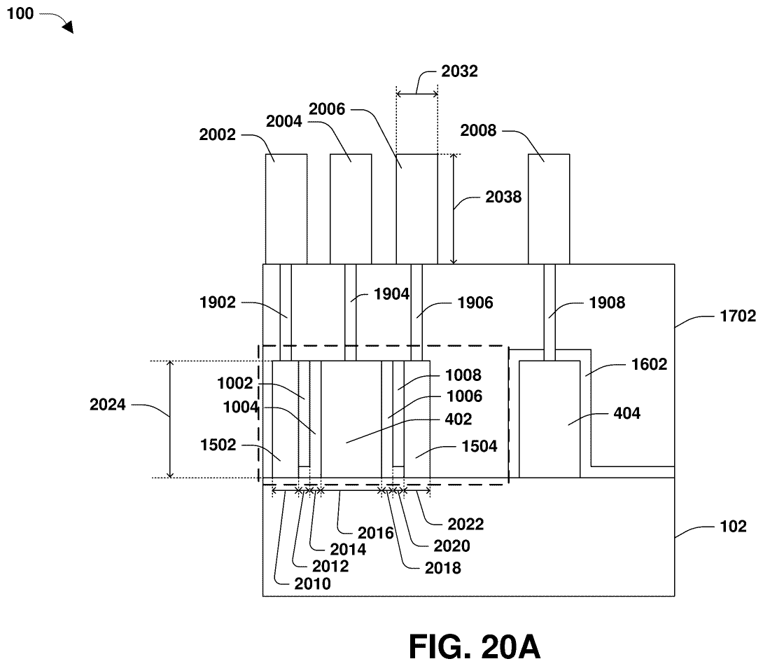

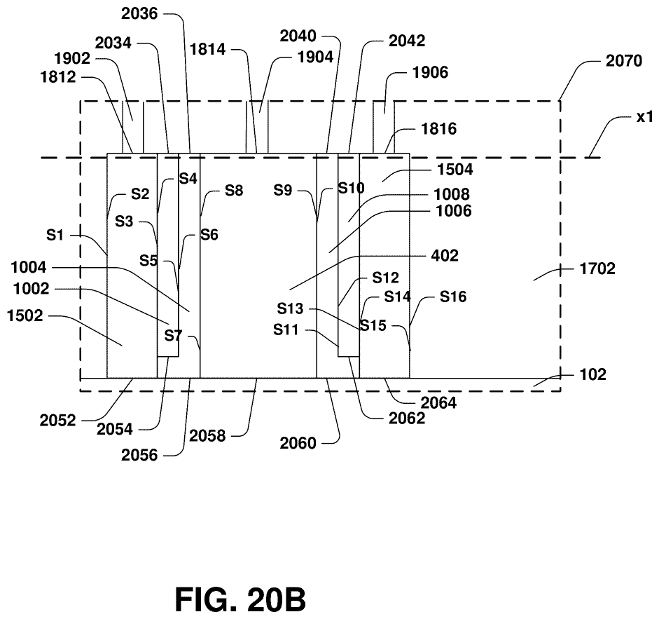

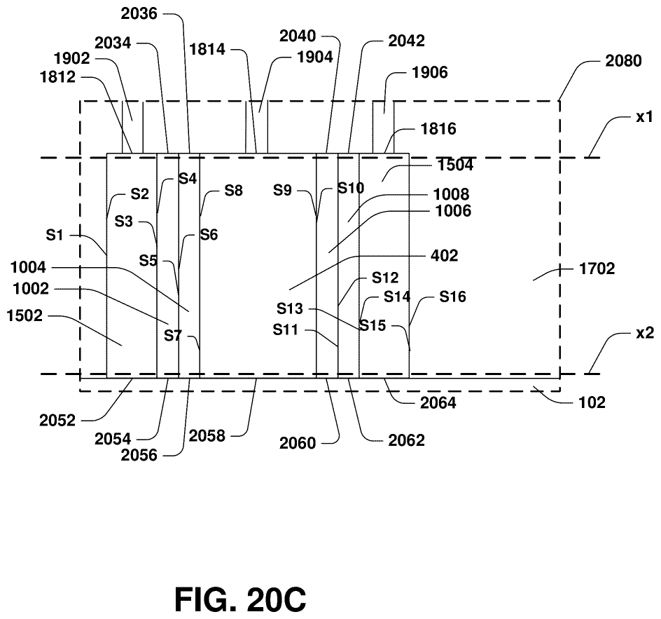

FIG. 20A illustrates a set of terminals formed over the set of vias and the dielectric layer 1702, according to some embodiments. In some embodiments, the set of terminals comprises at least one of (i) a first terminal 2002 formed over the first via 1902, which extends through the dielectric layer 1702 from the first terminal 2002 to the third electrode 1502, (ii) a second terminal 2004 formed over the second via 1904, which extends through the dielectric layer 1702 from the second terminal 2004 to the first electrode 402, (iii) a third terminal 2006 formed over the third via 1906, which extends through the dielectric layer 1702 from the third terminal 2006 to the fourth electrode 1504, or (iv) a fourth terminal 2008 formed over the fourth via 1908, which extends through at least one the dielectric layer 1702 or the third metal layer 1602 from the fourth terminal 2008 to the second electrode 404. One, some or all terminals of the set of terminals comprise at least one of a metal, a metal alloy, or other suitable material. Embodiments are contemplated in which a terminal of the set of terminals comprises a non-metal, such as a conductive non-metal. In some embodiments, one, some or all terminals of the set of terminals comprise at least one of aluminum, copper, titanium, or other suitable metal. In some embodiments, the set of terminals are formed by at least one of PVD, sputtering, CVD, PECVD, LPCVD, ALCVD, UHVCVD, RPCVD, ALD, MBE, LPE, spin on, growth, or other suitable techniques.

In some embodiments, at least one of (i) the first terminal 2002 is in contact (e.g., direct contact or indirect contact) with the first via 1902, (ii) the second terminal 2004 is in contact (e.g., direct contact or indirect contact) with the second via 1904, (iii) the third terminal 2006 is in contact (e.g., direct contact or indirect contact) with the third via 1906, or (iv) the fourth terminal 2008 is in contact (e.g., direct contact or indirect contact) with the fourth via 1908. In some embodiments, at least one of (i) the first via 1902 establishes an electrical connection between the first terminal 2002 and the third electrode 1502, (ii) the second via 1904 establishes an electrical connection between the second terminal 2004 and the first electrode 402, (iii) the third via 1906 establishes an electrical connection between the third terminal 2006 and the fourth electrode 1504, or (iv) the fourth via 1908 establishes an electrical connection between the fourth terminal 2008 and the second electrode 404. In some embodiments, at least one of the fourth terminal 2008 or the second electrode 404 is used to apply a voltage to at least one of the semiconductor body 102 or a component (not shown) in the semiconductor body 102.

In some embodiments, at least one of the first terminal 2002 or the second terminal 2004 are used for at least one of (i) controlling the first capacitor, (ii) applying a voltage to the first capacitor, (iii) charging the first capacitor, such as by way of supplying electrical energy to the first capacitor via the first terminal 2002 and/or the second terminal 2004 and/or storing the electrical energy in at least one of the first nitride structure 1002 or the first oxide structure 1004, or (iv) discharging the first capacitor, such as by way of supplying stored electrical energy to a first load via at least one of the first terminal 2002 or the second terminal 2004. In some embodiments, the first capacitor is charged and/or discharged by applying a signal (e.g., a square wave, a control signal) to the first capacitor via at least one of the first terminal 2002 or the second terminal 2004. In some embodiments, the first load comprises at least one of an internal load inside the semiconductor device 100 or an external load outside the semiconductor device 100, such as at least one of a second wafer, circuitry outside the semiconductor device 100, etc. In some embodiments, the first load is electrically connected to the first capacitor via the first terminal 2002 and the second terminal 2004.

In some embodiments, at least one of the third terminal 2006 or the second terminal 2004 are used for at least one of (i) controlling the second capacitor, (ii) applying a voltage to the second capacitor, (iii) charging the second capacitor, such as by way of supplying electrical energy to the second capacitor via the third terminal 2006 and/or the second terminal 2004 and/or storing the electrical energy in at least one of the second nitride structure 1008 or the second oxide structure 1006, or (iv) discharging the second capacitor, such as by way of supplying stored electrical energy to a second load via at least one of the third terminal 2006 or the second terminal 2004. In some embodiments, the second capacitor is charged and/or discharged by applying a signal (e.g., a square wave, a control signal) to the second capacitor via at least one of the third terminal 2006 or the second terminal 2004. In some embodiments, the second load comprises at least one of an internal load inside the semiconductor device 100 or an external load outside the semiconductor device 100, such as at least one of a third wafer, circuitry outside the semiconductor device 100, etc. In some embodiments, the second load is electrically connected to the second capacitor via the third terminal 2006 and the second terminal 2004.

A width 2010 of the third electrode 1502 is at least one of (i) between about 500 angstroms to about 1500 angstroms, (ii) between about 800 angstroms to about 1200 angstroms, or (iii) about 1000 angstroms. A width 2012 of the first nitride structure 1002 is at least one of (i) between about 100 angstroms to about 1000 angstroms, (ii) between about 300 angstroms to about 500 angstroms, or (iii) about 400 angstroms. A width 2014 of the first oxide structure 1004 is at least one of (i) between about 100 angstroms to about 1000 angstroms, (ii) between about 300 angstroms to about 500 angstroms, or (iii) about 400 angstroms. A width 2016 of the first electrode 402 is at least one of (i) between about 1000 angstroms to about 10000 angstroms, or (ii) between about 3000 angstroms to about 5000 angstroms. A width 2018 of the second oxide structure 1006 is at least one of (i) between about 100 angstroms to about 1000 angstroms, (ii) between about 300 angstroms to about 500 angstroms, or (iii) about 400 angstroms. A width 2020 of the second nitride structure 1008 is at least one of (i) between about 100 angstroms to about 1000 angstroms, (ii) between about 300 angstroms to about 500 angstroms, or (iii) about 400 angstroms. A width 2022 of the fourth electrode 1504 is at least one of (i) between about 500 angstroms to about 1500 angstroms, (ii) between about 800 angstroms to about 1200 angstroms, or (iii) about 1000 angstroms. A height 2024 of at least one of the third electrode 1502, the first nitride structure 1002, the first oxide structure 1004, the first electrode 402, the second oxide structure 1006, the second nitride structure 1008, or the fourth electrode 1504 is at least one of (i) between about 4000 angstroms to about 10000 angstroms, or (ii) between about 6000 angstroms to about 8000 angstroms. A height 2038 of each terminal of one, some, or all of the set of terminals is at least one of (i) between about 6000 angstroms to about 10000 angstroms, (ii) between about 7000 angstroms to about 9000 angstroms, or (iii) about 8000 angstroms. A width 2032 of each terminal of one, some, or all of the set of terminals is between about 1000 angstroms to about 5000 angstroms. Other values of the width 2010, the width 2012, the width 2014, the width 2016, the width 2018, the width 2020, the width 2022, the height 2024, the height 2038, and the width 2032 are within the scope of the present disclosure.

In some embodiments, the width of the first insulation structure 1010 (shown in FIGS. 10-19) corresponds to a sum of the width 2012 of the first nitride structure 1002 and the width 2014 of the first oxide structure 1004. In some embodiments, the width of the second insulation structure 1012 (shown in FIGS. 10-19) corresponds to a sum of the width 2018 of the second oxide structure 1006 and the width 2020 of the second nitride structure 1008.

FIGS. 20B-20C illustrate enlarged representations of different versions of a section 2050 (shown in FIG. 2A with a dashed-line outline) of the semiconductor device 100, according to some embodiments. FIG. 20B illustrates a first enlarged representation 2070 of the section 2050 of the semiconductor device 100, according to some embodiments. In some embodiments, the third electrode 1502 comprises at least one of (i) a sidewall S2 adjacent a sidewall S1 of the dielectric layer or (ii) a sidewall S3 adjacent a sidewall S4 of the first nitride structure 1002. In some embodiments, at least one of (i) the sidewall S2 is at least one of aligned with or in contact (e.g., direct contact or indirect contact) with the sidewall S1 of the dielectric layer or (ii) the sidewall S3 is at least one of aligned with or in contact (e.g., direct contact or indirect contact) with the sidewall S4 of the first nitride structure 1002. In some embodiments, the first nitride structure 1002 comprises a sidewall S5 adjacent a sidewall S6 of the first oxide structure 1004. In some embodiments, the sidewall S5 of the first nitride structure 1002 is at least one of aligned with or in contact (e.g., direct contact or indirect contact) with the sidewall S6 of the first oxide structure 1004. In some embodiments, the first oxide structure 1004 comprises a sidewall S7 adjacent a sidewall S8 of the first electrode 402. In some embodiments, the sidewall S7 of the first oxide structure 1004 is at least one of aligned with or in contact (e.g., direct contact or indirect contact) with the sidewall S8 of the first electrode 402. In some embodiments, the first electrode 402 comprises a sidewall S9 adjacent a sidewall S10 of the second oxide structure 1006. In some embodiments, the sidewall S9 of the first electrode 402 is at least one of aligned with or in contact (e.g., direct contact or indirect contact) with the sidewall S10 of the second oxide structure 1006. In some embodiments, the second oxide structure 1006 comprises a sidewall S11 adjacent a sidewall S12 of the second nitride structure 1008. In some embodiments, the sidewall S11 of the second oxide structure 1006 is at least one of aligned with or in contact (e.g., direct contact or indirect contact) with the sidewall S12 of the second nitride structure 1008. In some embodiments, the second nitride structure 1008 comprises a sidewall S13 adjacent a sidewall S14 of the fourth electrode 1504. In some embodiments, the sidewall S13 of the second nitride structure 1008 is at least one of aligned with or in contact (e.g., direct contact or indirect contact) with the sidewall S14 of the fourth electrode 1504. In some embodiments, the fourth electrode 1504 comprises a sidewall S15 adjacent a sidewall S16 of the dielectric layer 1702. In some embodiments, the sidewall S15 of the fourth electrode 1504 is at least one of aligned with or in contact (e.g., direct contact or indirect contact) with the sidewall S16 of the dielectric layer 1702.

In some embodiments, the sidewall S7 of the first oxide structure 1004 corresponds to a first sidewall of the first insulation structure 1010. In some embodiments, the sidewall S4 of the first nitride structure 1002 corresponds to a second sidewall of the first insulation structure 1010. In some embodiments, the sidewall S10 of the second oxide structure 1006 corresponds to a first sidewall of the second insulation structure 1012. In some embodiments, the sidewall S13 of the second nitride structure 1008 corresponds to a second sidewall of the second insulation structure 1012.

Although FIGS. 1-20C show the first oxide structure 1004 between the first nitride structure 1002 and the first electrode 402, embodiments are contemplated in which the first nitride structure 1002 is arranged between the first oxide structure 1004 and the first electrode 402. Although FIGS. 1-20C show the second oxide structure 1006 between the second nitride structure 1008 and the first electrode 402, embodiments are contemplated in which the second nitride structure 1008 is arranged between the second oxide structure 1006 and the first electrode 402.

In some embodiments, some or all components of a set of components of the dual-capacitor structure 1706 are coplanar such that a plane (e.g., a single plane comprising a horizontal line x1 shown in FIG. 20B) passes through and/or intersects with some or all the components. In some embodiments, the set of components comprise at least one of the third electrode 1502, the first nitride structure 1002, the first oxide structure 1004, the first electrode 402, the second oxide structure 1006, the second nitride structure 1008, or the fourth electrode 1504. In some embodiments, components of the set of components have different elevations (e.g., slightly different elevations), and the set of components are coplanar such that a plane passes through and/or intersect with components of the set of components (even though top surfaces and/or bottom surfaces of the components may not be coplanar).

In some embodiments, some or all portions of a first set of portions of the set of components of the dual-capacitor structure 1706 are coplanar such that a plane (e.g., a single plane comprising the horizontal line x1) passes through and/or intersects with some or all the portions. In some embodiments, the first set of portions comprise upper portions of the set of components of the dual-capacitor structure 1706. In some embodiments, the first set of portions comprise at least one of (i) the portion 1812 of the third electrode 1502, (ii) a portion 2034 of the first nitride structure 1002, (iii) a portion 2036 of the first oxide structure 1004, (iv) the portion 1814 of the first electrode 402, (v) a portion 2040 of the second oxide structure 1006, (vi) a portion 2042 of the second nitride structure 1008, or (vii) the portion 1816 of the fourth electrode 1504. In some embodiments, at least one of (i) the portion 1812 of the third electrode 1502 comprises a top surface of the third electrode 1502, (ii) the portion 2034 of the first nitride structure 1002 comprises a top surface of the first nitride structure 1002, (iii) the portion 2036 of the first oxide structure 1004 comprises a top surface of the first oxide structure 1004, (iv) the portion 1814 of the first electrode 402 comprises a top surface of the first electrode 402, (v) the portion 2040 of the second oxide structure 1006 comprises a top surface of the second oxide structure 1006, (vi) the portion 2042 of the second nitride structure 1008 comprises a top surface of the second nitride structure 1008, or (vii) the portion 1816 of the fourth electrode 1504 comprises a top surface of fourth electrode 1504. In some embodiments, some or all top surfaces of the set of components are coplanar such that a plane passes through and/or intersects with some or all the top surfaces. In some embodiments, top surfaces of the set of components are not coplanar (e.g., the top surfaces could have slightly different elevations), and some or all of the first set of portions are coplanar.

FIG. 20C illustrates a second enlarged representation 2080 of the section 2050 of the semiconductor device 100, according to some embodiments. In some embodiments, some or all portions of a second set of portions of the set of components of the dual-capacitor structure 1706 are coplanar such that a plane (e.g., a plane comprising a horizontal line x2 in FIG. 20C) passes through and/or intersects with some or all the portions. In some embodiments, the second set of portions comprise lower portions of the set of components of the dual-capacitor structure 1706. In some embodiments, the second set of portions comprise at least one of (i) a portion 2052 of the third electrode 1502, (ii) a portion 2054 of the first nitride structure 1002, (iii) a portion 2056 of the first oxide structure 1004, (iv) a portion 2058 of the first electrode 402, (v) a portion 2060 of the second oxide structure 1006, (vi) a portion 2062 of the second nitride structure 1008, or (vii) a portion 2064 of the fourth electrode 1504. In some embodiments, at least one of (i) the portion 2052 of the third electrode 1502 comprises a bottom surface of the third electrode 1502, (ii) the portion 2054 of the first nitride structure 1002 comprises a bottom surface of the first nitride structure 1002, (iii) the portion 2056 of the first oxide structure 1004 comprises a bottom surface of the first oxide structure 1004, (iv) the portion 2058 of the first electrode 402 comprises a bottom surface of the first electrode 402, (v) the portion 2060 of the second oxide structure 1006 comprises a bottom surface of the second oxide structure 1006, (vi) the portion 2062 of the second nitride structure 1008 comprises a bottom surface of the second nitride structure 1008, or (vii) the portion 2064 of the fourth electrode 1504 comprises a bottom surface of fourth electrode 1504. In some embodiments, some or all bottom surfaces of the set of components are coplanar such that a plane passes through and/or intersects with some or all the bottom surfaces. In some embodiments, bottom surfaces of the set of components are not coplanar (e.g., the bottom surfaces could have slightly different elevations), and some or all of the second set of portions are coplanar.

Embodiments are contemplated in which all bottom surfaces of the set of components are coplanar (and/or aligned with the semiconductor body 102), such as shown in the second enlarged representation 2080 of FIG. 20C. Embodiments are contemplated in which merely some bottom surfaces of the set of components are coplanar (and/or aligned with the semiconductor body 102), such as shown in the first enlarged representation 2070 of FIG. 20B, where the bottom surface of the first nitride structure 1002 and/or the bottom surface of the second nitride structure 1008 are at a higher elevation than other bottom surfaces of other components of the set of components.

In some embodiments, arranging the set of components in accordance with the present disclosure to form the first capacitor and the second capacitor provides for at least one of (i) increased quantity of capacitors in the semiconductor device 100 as a result of capacitors taking up less space, such as due, at least in part, to the first capacitor and the second capacitor sharing the first electrode 402, (ii) enlarged MIM capacitors in parallel, (iii) reduced size of the semiconductor device 100 as a result of capacitors taking up less space, such as due, at least in part, to the first capacitor and the second capacitor sharing the first electrode 402, etc. In some embodiments, some systems vertically stack capacitor components (e.g., a first metal plate, an insulation plate, and a second metal plate) in a vertical arrangement to form a MIM capacitor. However, those systems may at least one of (i) require use of at least one of an extra mask or an anti-reflective coating (ARC) layer to form the MIM capacitor, thereby resulting in increased cost of forming the MIM capacitor or (ii) be associated with deformation of the MIM capacitor. Thus, in accordance with some embodiments, arranging the set of components in accordance with the present disclosure provides for at least one of (i) reduced cost of forming a MIM capacitor (such as due, at least in part, to not requiring at least one of the extra mask or the ARC layer to form the MIM capacitor), (ii) improved quality of the MIM capacitor, etc.

In some embodiments, the semiconductor device 100 comprises a plurality of capacitors comprising the first capacitor, the second capacitor, and other capacitors (not shown) formed using one or more of the techniques provided herein with respect to forming the first capacitor and the second capacitor. In some embodiments, the semiconductor device 100 comprises non-capacitor components, such as at least one of a transistor, a diode, a logic component, etc.

In some embodiments, a semiconductor device is provided. The semiconductor device includes a first capacitor and a second capacitor. The first capacitor includes a first electrode, a second electrode, a first oxide structure between the first electrode and the second electrode, and a first nitride structure between the first electrode and the second electrode. The second capacitor includes the second electrode, a third electrode, a second oxide structure between the second electrode and the third electrode, and a second nitride structure between the second electrode and the third electrode.

In some embodiments, a method of forming a semiconductor device is provided. The method includes forming a first metal layer over a semiconductor body. The method includes patterning the first metal layer to form a first electrode over the semiconductor body. The method includes forming a nitride layer and an oxide layer over the semiconductor body. The method includes patterning the nitride layer and the oxide layer to form a first insulation structure including a first sidewall adjacent a first sidewall of the first electrode and a second insulation structure including a first sidewall adjacent a second sidewall of the first electrode. The method includes forming a second metal layer over the semiconductor body. The method includes patterning the second metal layer to form a second electrode including a first sidewall adjacent a second sidewall of the first insulation structure and a third electrode including a first sidewall adjacent a second sidewall of the second insulation structure.

In some embodiments, a semiconductor device is provided. The semiconductor device includes a first MIM capacitor and a second MIM capacitor. The first MIM capacitor includes a first electrode, a second electrode, and a first insulation structure between the first electrode and the second electrode. The second MIM capacitor includes the second electrode, a third electrode, and a second insulation structure between the second electrode and the third electrode.

Although the subject matter has been described in language specific to structural features or methodological acts, it is to be understood that the subject matter of the appended claims is not necessarily limited to the specific features or acts described above. Rather, the specific features and acts described above are disclosed as example forms of implementing at least some of the claims.

Various operations of embodiments are provided herein. The order in which some or all of the operations are described should not be construed to imply that these operations are necessarily order dependent. Alternative ordering will be appreciated having the benefit of this description. Further, it will be understood that not all operations are necessarily present in each embodiment provided herein. Also, it will be understood that not all operations are necessary in some embodiments.

It will be appreciated that layers, features, elements, etc. depicted herein are illustrated with particular dimensions relative to one another, such as structural dimensions or orientations, for example, for purposes of simplicity and ease of understanding and that actual dimensions of the same differ substantially from that illustrated herein, in some embodiments. Additionally, a variety of techniques exist for forming layers, regions, features, elements, etc. mentioned herein, such as at least one of etching techniques, planarization techniques, implanting techniques, doping techniques, spin-on techniques, sputtering techniques, growth techniques, or deposition techniques such as chemical vapor deposition (CVD), for example.

Moreover, “exemplary” and/or the like is used herein to mean serving as an example, instance, illustration, etc., and not necessarily as advantageous. As used in this application, “or” is intended to mean an inclusive “or” rather than an exclusive “or”. In addition, “a” and “an” as used in this application and the appended claims are generally be construed to mean “one or more” unless specified otherwise or clear from context to be directed to a singular form. Also, at least one of A and B and/or the like generally means A or B or both A and B. Furthermore, to the extent that “includes”, “having”, “has”, “with”, or variants thereof are used, such terms are intended to be inclusive in a manner similar to the term “comprising”. Also, unless specified otherwise, “first,” “second,” or the like are not intended to imply a temporal aspect, a spatial aspect, an ordering, etc. Rather, such terms are merely used as identifiers, names, etc. for features, elements, items, etc. For example, a first element and a second element generally correspond to element A and element B or two different or two identical elements or the same element.

Also, although the disclosure has been shown and described with respect to one or more implementations, equivalent alterations and modifications will occur to others of ordinary skill in the art based upon a reading and understanding of this specification and the annexed drawings. The disclosure comprises all such modifications and alterations and is limited only by the scope of the following claims. In particular regard to the various functions performed by the above described components (e.g., elements, resources, etc.), the terms used to describe such components are intended to correspond, unless otherwise indicated, to any component which performs the specified function of the described component (e.g., that is functionally equivalent), even though not structurally equivalent to the disclosed structure. In addition, while a particular feature of the disclosure may have been disclosed with respect to only one of several implementations, such feature may be combined with one or more other features of the other implementations as may be desired and advantageous for any given or particular application.

What is claimed is:

1. A semiconductor device, comprising:
a first capacitor comprising:
a first electrode;
a second electrode;
a first oxide structure between the first electrode and the second electrode; and
a first nitride structure between the first electrode and the second electrode; and
a second capacitor comprising:
the second electrode;
a third electrode;
a second oxide structure between the second electrode and the third electrode; and
a second nitride structure between the second electrode and the third electrode.

2. The semiconductor device of claim 1, comprising:
a semiconductor body; and
a dielectric layer overlying the semiconductor body, wherein the first capacitor and the second capacitor are in the dielectric layer.

3. The semiconductor device of claim 2, comprising:
a first terminal, a second terminal, and a third terminal overlying the dielectric layer;
a first via extending through the dielectric layer from the first terminal to the first electrode;
a second via extending through the dielectric layer from the second terminal to the second electrode; and
a third via extending through the dielectric layer from the third terminal to the third electrode.

4. The semiconductor device of claim 3, wherein:
the first via is in contact with a portion of the first electrode;
the second via is in contact with a portion of the second electrode;
the third via is in contact with a portion of the second electrode; and
at least one of:
the portion of the first electrode is coplanar with the portion of the second electrode;
the portion of the second electrode is coplanar with the portion of the third electrode; or
the portion of the first electrode is coplanar with the portion of the third electrode.

5. The semiconductor device of claim 1, wherein at least one of:
the first nitride structure comprises silicon nitride; or
the second nitride structure comprises silicon nitride.

6. The semiconductor device of claim 1, wherein at least one of:
the first electrode comprises titanium nitride; or
the third electrode comprises titanium nitride.

7. The semiconductor device of claim 1, wherein:
the second electrode comprises at least one of aluminum or copper.

8. The semiconductor device of claim 1, wherein at least one of:
the first oxide structure is between the first nitride structure and the second electrode; or
the second oxide structure is between the second nitride structure and the second electrode.

9. The semiconductor device of claim 1, wherein at least one of:
the first nitride structure is between the first oxide structure and the second electrode; or
the second nitride structure is between the second oxide structure and the second electrode.

10. A method of forming a semiconductor device, comprising:
forming a first metal layer over a semiconductor body;
patterning the first metal layer to form a first electrode over the semiconductor body;
forming a nitride layer and an oxide layer over the semiconductor body;
patterning the nitride layer and the oxide layer to form:
a first insulation structure comprising a first sidewall adjacent a first sidewall of the first electrode; and
a second insulation structure comprising a first sidewall adjacent a second sidewall of the first electrode;
forming a second metal layer over the semiconductor body; and
patterning the second metal layer to form:
a second electrode comprising a first sidewall adjacent a second sidewall of the first insulation structure; and
a third electrode comprising a first sidewall adjacent a second sidewall of the second insulation structure.

11. The method of claim 10, comprising:
forming a dielectric layer over the semiconductor body, wherein the dielectric layer comprises:
a first sidewall adjacent a second sidewall of the second electrode; and
a second sidewall adjacent a second sidewall of the third electrode.

12. The method of claim 11, comprising:
forming a first trench in the dielectric layer to expose a portion of the first electrode;
forming a second trench in the dielectric layer to expose a portion of the second electrode; and
forming a third trench in the dielectric layer to expose a portion of the third electrode.

13. The method of claim 12, comprising:
forming a via in the first trench; and
forming a terminal over the via, wherein the via electrically connects the terminal to the first electrode.

14. The method of claim 12, comprising:
forming a via in the second trench; and
forming a terminal over the via, wherein the via electrically connects the terminal to the second electrode.

15. The method of claim 12, comprising:
forming a via in the third trench; and
forming a terminal over the via, wherein the via electrically connects the terminal to the third electrode.

16. A semiconductor device, comprising:
a first metal-insulator-metal (MIM) capacitor comprising:
a first electrode;
a second electrode; and
a first insulation structure between the first electrode and the second electrode; and
a second MIM capacitor comprising:
the second electrode;
a third electrode; and
a second insulation structure between the second electrode and the third electrode.

17. The semiconductor device of claim 16, comprising:
a semiconductor body; and
a dielectric layer overlying the semiconductor body, wherein the first MIM capacitor and the second MIM capacitor are in the dielectric layer.

18. The semiconductor device of claim 17, comprising:
a first terminal, a second terminal, and a third terminal overlying the dielectric layer;
a first via extending through the dielectric layer from the first terminal to the first electrode;
a second via extending through the dielectric layer from the second terminal to the second electrode; and
a third via extending through the dielectric layer from the third terminal to the third electrode.

19. The semiconductor device of claim 18, wherein:
the first via is in contact with a portion of the first electrode;
the second via is in contact with a portion of the second electrode;
the third via is in contact with a portion of the second electrode; and
at least one of:
the portion of the first electrode is coplanar with the portion of the second electrode;
the portion of the second electrode is coplanar with the portion of the third electrode; or
the portion of the first electrode is coplanar with the portion of the third electrode.

20. The semiconductor device of claim 16, wherein at least one of:
the first electrode comprises at least one of aluminum or copper;
the second electrode comprises titanium nitride; or
the third electrode comprises titanium nitride.
